(19) United States
(12) Patent Application Publication
(10) Pub. No.: US 2001/0034110 A1
(43) Pub. Date: Oct. 25, 2001

(54) METHOD OF TRANSFORMING OTP ROM MANUFACTURING PROCESS INTO ROM MANUFACTURING PROCESS

(76) Inventor: KUANG-YEH CHANG, TAIPEI CITY (TW)

Correspondence Address: KNOBBE, MARTENS, OLSON & BEAR, P.O. BOX 19242, IRVINE, CA, 92623-9242, US

(21) Appl. No.: 09/182,137

(22) Filed: Oct. 29, 1998

(30) Foreign Application Priority Data
Jun. 20, 1998 (TW) 87109961

(51) Int. Cl. C30B 1/00

(52) U.S. Cl. 438/480

(57) ABSTRACT

A method of transforming the OTP ROM manufacturing process into the ROM manufacturing process comprises a check step for checking the OTP ROM manufacturing process to determine which manufacturing step is already performed. If the step of depositing the polysilicon layer, acting a control gate, has already been performed, a standard OTP ROM manufacturing process is then performed. Thereafter, a coding energy is performed, in which the coding energy is about 50 KeV higher than a standard coding energy. If the step of depositing the polysilicon layer, acting a control gate, has not yet been performed, then the coding energy is about a standard coding energy. Whatever step the ongoing OTP ROM manufacturing process is on, the present invention can transform the OTP ROM manufacturing process into the ROM manufacturing process to produce ROM by the direct implanting step. It isn't necessary to redesign the masks. The size of the OTP ROM is approximately the same as the ROM so that no die surface is sacrificed.

### BACKGROUND OF THE INVENTION

1. Field of Invention

This invention relates generally to method of manufacturing a memory structure, and more particularly to method of transforming a one time program read only memory (OTP ROM) manufacturing process into a read only memory manufacturing process.

2. Background

As the function of the microprocessor becomes stronger and the program and the operation of software increase, the requirement for memory becomes higher. Therefore, it is now the most important subject of semiconductor manufacturers to fabricate low-cost and high-density memories. Memories can be divided into two categories: read only memories (ROM) and random access memories. ROMs further include mask ROMs, programmable ROMs (PROM), erasable programmable ROMs (EPROM) and electrically erasable programmable ROMs (EEPROM). Random access memories include static random access memories (SRAM) and dynamic random access memories (DRAM).

ROMs are widely used in digital equipment such as personal computers and microprocessors. The process for fabricating ROMs is rather complicated and time-consuming. The processes for fabricating different types of ROMs are more or less the same except that the data stored in the programming are different. Therefore, ROMs are always manufactured as semi-product. As the programs from the clients are received, the particular ROMs can be quickly completed, simply by forming masks to program the ROMs.

Usually, ROMs use channel transistors as memory cells. During programming, dopants are selectively implanted into certain channel regions to modify the threshold voltage and to control memory cells ON/OFF. ROMs include polysilicon word lines (WL) crossing bit lines (BL). The channel of a memory cell is below a word line WL and between two bit lines BLs. The implantation of ions into the channel determines the binary data “0” or “1”.

FIG. 1 is a schematic layout of a conventional EPROM. FIG. 2 is cross sectional view taken along the line I-I in FIG. 1. FIG. 3 is cross sectional view taken along the line II-II in FIG. 1. The manufacturing method of the conventional EPROM is described below.

Referring to FIGS. 1, 2 and 3, first, on a substrate 10, a pad oxide layer (not shown) is formed by thermal oxidation. Active regions are then defined by forming field oxide layer 14, using local oxidation. The pad oxide layer is then removed by wet etching. Next, by thermal oxidation, an oxide layer 12 is formed on the surface of the device regions. Then, a layer of polysilicon material is formed on the oxide layer 12 by low pressure chemical vapor deposition (LPCVD). The polysilicon material layer is then defined by photolithography and etching to form a polysilicon layer 16.

Next, a layer of inter-poly dielectric material is formed by LPCVD, and covers the polysilicon layer 16. Then, another layer of polysilicon material is formed on the polysilicon layer 16. Both the inter-poly dielectric material layer and the polysilicon layer are patterned by photolithography and etching to form an inter-poly dielectric layer 18 and polysilicon layer 20, respectively.

Then, by using the polysilicon layer 20 as a mask, the polysilicon layer 16 is further patterned by etching. A process of implanting ions is next performed by using the polysilicon layer 20 as a mask to form an implantation region 22 with a higher density of doped ions than that of the substrate. A dielectric layer 24 is formed over the whole substrate structure by using LPCVD. A contact opening 26 is formed on the dielectric layer 24, exposing the implantation region 22, by using lithography and etching. Then, a metal layer 28 acting as a bit line is formed over the dielectric layer 24 by LPCVD, filling the contact opening 26 so that the metal layer 28, also known as the bit line, is electrically coupled to the implantation region 22. A conventional procedure is followed to complete fabrication of the EPROM. This procedure is familiar to those skilled in the art and therefore is not described here.

In the conventional method described above, it is difficult to effectively reduce the memory size because it is limited by the size of the contact opening 26. The existence of the field oxide layer 14 also affects the size reduction and planarization of the active region. Besides that, since the metal layer 28 also has to fill the contact opening 26 in order to serve as the bit line, interference due to signal reflection from the metal layer 28 is inevitable during the etching step.

FIG. 4 is a schematic layout of a conventional ROM. FIG. 5 is cross sectional view taken along the line III-III in FIG. 4. FIG. 6 is cross sectional view taken along the line IV-IV in FIG. 4.

As shown in FIG. 4, a conventional read only memory includes a substrate 30 having an oxide layer 31 formed thereon. Implanting regions 32 which are parallel to each other are formed on/near the surface of the substrate 30. Conductive layers 34 which are parallel to each other are formed on the substrate 30. Each implanting region 32 and conductive layer are perpendicular each other and are arranged in arrays.

The redesign of the masks is unavoidable in the process of transforming EPROM (FIG. 1) into ROM (FIG. 4), because of the large structural difference between EPROM and ROM. Therefore, the conventional transforming process takes time and manpower and is expensive. Moreover, it is necessary to reprove the masks after the masks are redesigned.

### SUMMARY OF THE INVENTION

It is therefore an objective of the present invention to provide a method of transforming OTP ROM manufacturing process into ROM manufacturing process for solving one or more of the conventional problems.

The invention achieves the above-identified objects by providing a method of transforming OTP ROM manufacturing process into ROM manufacturing process, that comprises providing a substrate having two polysilicon layers formed thereon; using an implanting energy to perform a coding step, wherein the implanting energy is about 200 KeV to 300 KeV; forming a passivation layer over the substrate; performing a data erasing step; and performing a test step.

The invention achieves the above-identified objects by providing another method of transforming OTP ROM manufacturing process into ROM manufacturing process, that comprises the steps of: providing a substrate having a polysilicon layer formed thereon; using an implanting energy to perform a coding step, wherein the implanting energy is about 150 KeV to 200 KeV; and performing a test step.

Whatever step the ongoing OTP ROM manufacturing process is on, the present invention can transform the OTP ROM manufacturing process into the ROM manufacturing process to produce ROM by the direct implanting step. It isn't necessary to redesign the masks. The size of the OTP ROM is approximately the same as the ROM so that no die surface is sacrificed.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 is a schematic layout of a conventional EPROM;

FIG. 2 is a cross-sectional view taken along the line I-I in FIG. 1;

FIG. 3 is a cross-sectional view taken along the line II-II in FIG. 1;

FIG. 4 is a schematic layout of a conventional ROM;

FIG. 5 is a cross-sectional view taken along the line III-III in FIG. 4;

FIG. 6 is a cross-sectional view taken along the line IV-IV in FIG. 4;

FIG. 7 is a schematic layout of an OTP ROM;

FIGS. 8A to 8C are cross-sectional views showing a process flow for fabricating an OTP ROM according to the present invention, in which

FIGS. 8A and 8B are cross-sectional views taken along the line V-V in FIG. 7 and

FIG. 8C is a cross-sectional view taken along the line VI-VI in FIG. 7;

FIG. 9 shows a process flow of transforming the OTP ROM manufacturing process into the ROM manufacturing process according to one embodiment of the present invention; and

FIG. 10 shows a process flow for transforming the OTP ROM manufacturing process into the ROM manufacturing process according to another embodiment of the present invention.

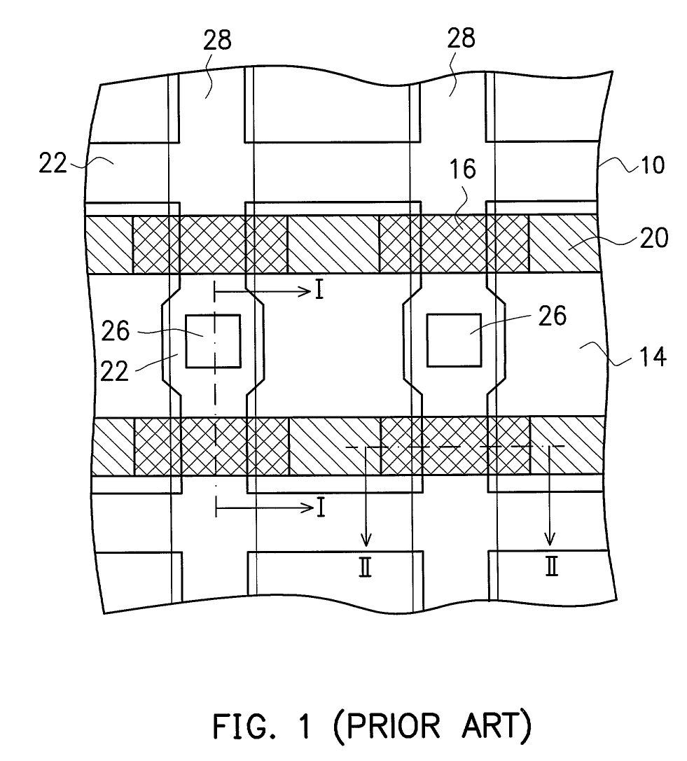

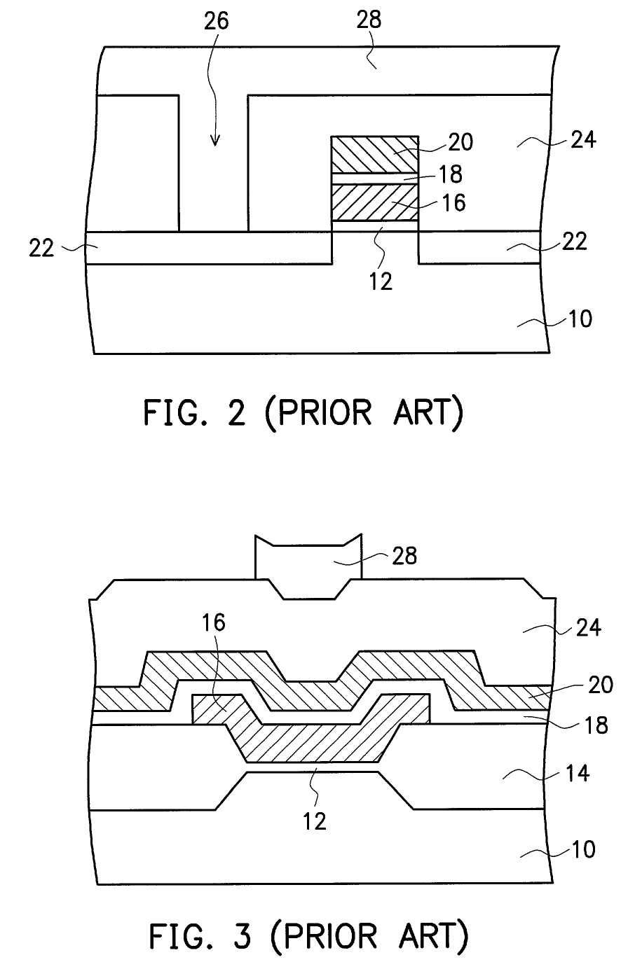

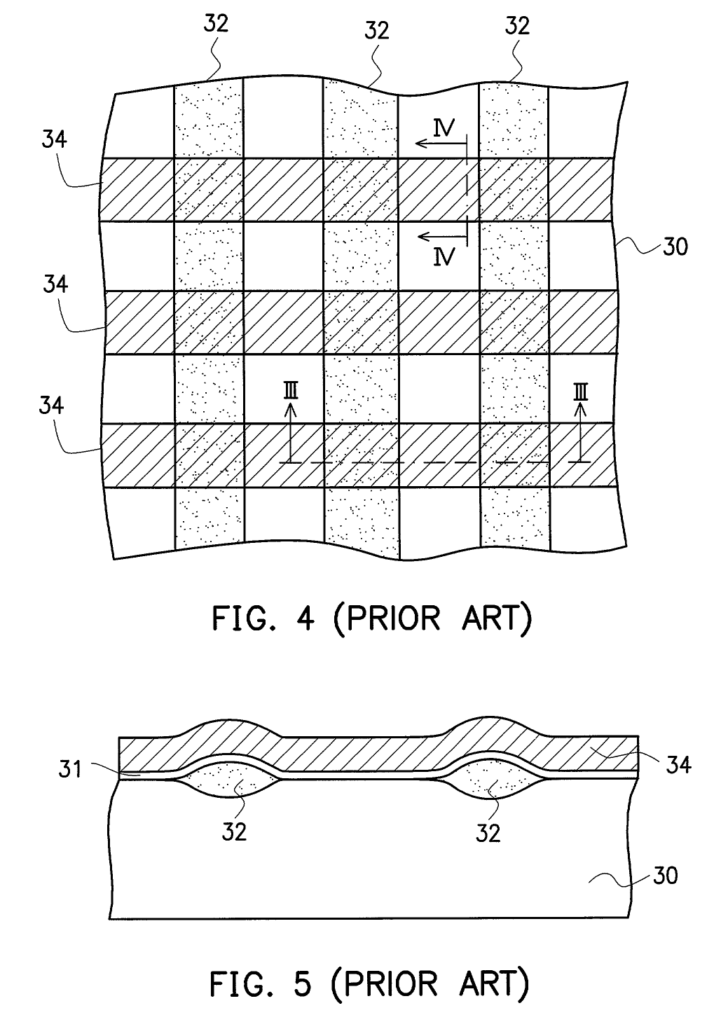

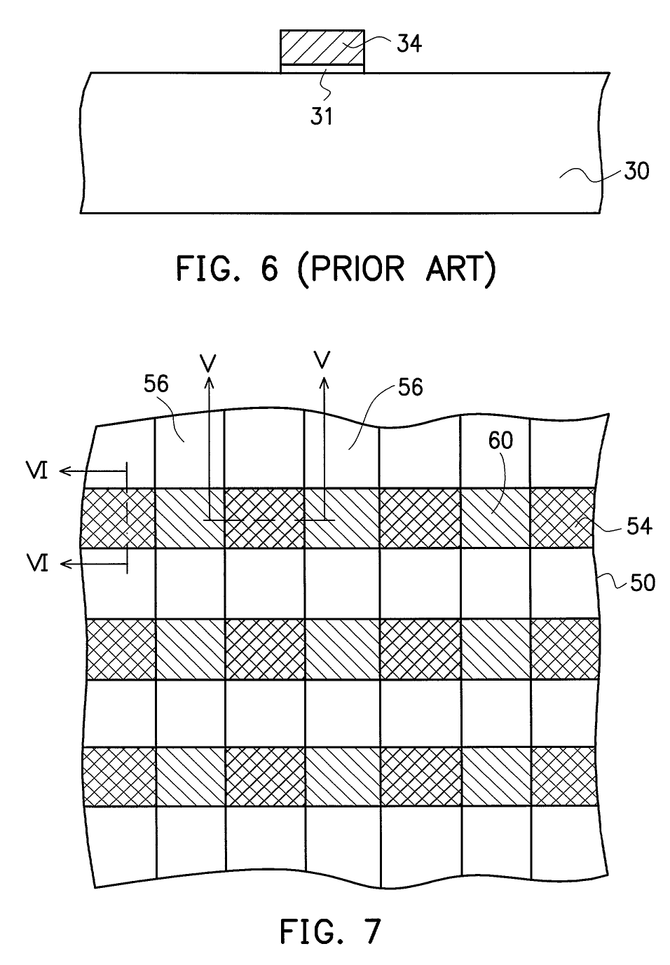

### DESCRIPTION OF THE PREFERRED EMBODIMENT

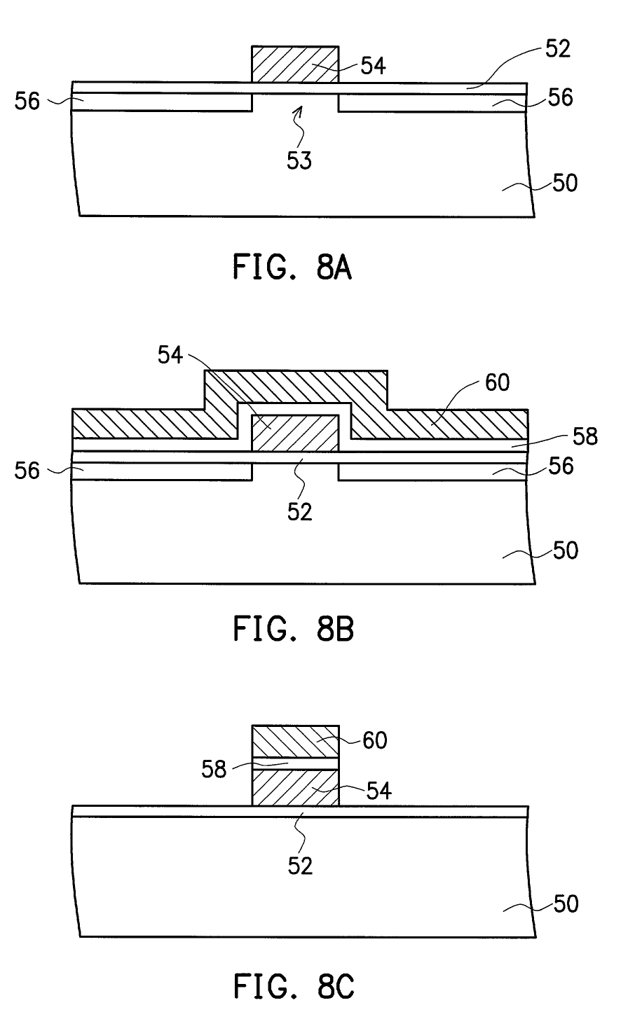

FIGS. 8A to 8C are cross-sectional views showing a process flow for fabricating an OTP ROM according to the present invention, FIGS. 8A and 8B are cross-sectional views taken along the line V-V in FIG. 7 and FIG. 8C is a cross-sectional view taken along the line VI-VI in FIG. 7.

Referring to FIG. 8A, a thermal oxidation process is performed on a semiconductor substrate 50 to form an oxide layer 52. Then, polysilicon material is deposited over the oxide layer 52 by LPCVD, and this polysilicon layer is patterned by photolithography and etching to form a polysilicon layer 54. The surface of the substrate 50 is exposed on both sides of the polysilicon layer 54.

Then, a self-aligned implanting process is performed by using the patterned polysilicon layer 54 as a mask to dope ions, for example, As ions, through the oxide layer 52 into the substrate 50 on both sides of the polysilicon layer 54. A process of annealing is performed to form implantation regions 56 acting as a buried bit line.

It is advantageous to have the implantation region 56 formed by performing a self-aligned technology.

Referring to FIG. 8B, next, an inter-poly dielectric layer 58 is formed by, for example, LPCVD, and covers the polysilicon layer 54 and oxide layer 52. The inter-poly dielectric layer 58 is constructed by oxide/nitride/oxide layers. Then, another layer 60 of polysilicon is formed by, for example, LPCVD, on the inter-poly dielectric layer 58.

Referring to FIG. 8C, the polysilicon layer 60 is patterned by using a mask (not shown) and etching process. The patterned polysilicon layer 60 is utilized as a control gate that is a word line. Thereafter, the same mask and etching process as used again to further etch the polysilicon layer 54 and inter-poly dielectric layer 58. The patterned polysilicon layer 54 is used as a floating gate. The etching step in the patterning process of the polysilicon layer 54 can be a self-aligned etching step. A conventional procedure is followed to complete fabrication of the OTP ROM. This procedure is familiar to those skilled in the art and therefore is not described here.

The invention advantageously uses an ion implanting process in a self-aligned technology, by using the polysilicon layer 54 as a mask to form a buried bit line 56. The contact opening is unnecessary and interference from the signal reflection of metal in the contact opening is avoided.

Moreover, since the field oxide layer is unnecessary in this invention, the size is greatly reduced and a higher quality of planarization of the active region is achieved.

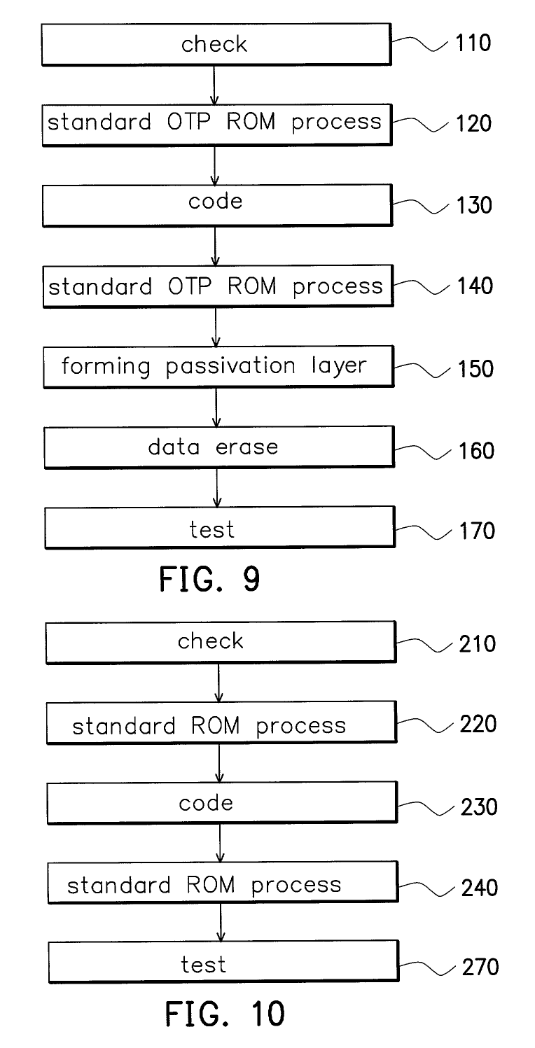

FIG. 9 shows a process flow for transforming the OTP ROM manufacturing process into the ROM manufacturing process according to one embodiment of the present invention.

Referring to FIGS. 9, 7 and 8A to 8C, first, in step 110, a check step is performed for checking the OTP ROM manufacturing process to know which process step has already been performed. If the step of depositing the polysilicon layer 60 has already been performed, of standard OTP ROM manufacturing process is then performed in step 120. Thereafter, in step 130, coding is performed to drive ions through the polysilicon layers 60 and 54 into the substrate 50 to form the implantation regions. The energy of the coding step 130, for example, 200 KeV to 300 KeV, is about 50 KeV higher than that of a standard coding step to implant the ions through the polysilicon layers 60 and 54 into the substrate 50. In step 140, a standard OTP ROM manufacturing process is then performed. Thereafter, a passivation layer, such as oxynitride, is formed in step 150, after which there is a data erasing step 160 which uses an ultraviolet (UV) ray. The passivation layer is composed of UV ray penetrable material. The ROM then undergoes standard ROM testing in step 170.

FIG. 10 shows a process flow for transforming the OTP ROM manufacturing process into the ROM manufacturing process according to another embodiment of the present invention.

Referring to FIGS. 10, 7 and 8A to 8C, first, in 210, a check step is performed for checking the OTP ROM manufacturing process to determine which manufacturing step has already been performed. If the step of depositing the polysilicon layer 60 has not yet been performed, a standard ROM manufacturing process is then performed in step 220. Thereafter, coding is performed in step 230 to drive ions through the polysilicon layer 54 into the substrate 50 to form the implantation regions. The energy of the coding step 230, for example, 150 KeV to 200 KeV, is approximately equal to the standard coding energy used to implant the ions through the polysilicon layer 54 into the substrate 50. A standard ROM manufacturing process is then performed in step 240. After the ROM is formed, it undergoes standard ROM testing in step 170.

Whatever step the ongoing OTP ROM manufacturing process is on, the present invention can transform the OTP ROM manufacturing process into the ROM manufacturing process to produce ROM by the direct implanting step. It isn't necessary to redesign the masks. The size of the OTP ROM is approximately the same as the ROM so that no die surface is sacrificed.

The invention has been described using an exemplary preferred embodiment. However, it is to be understood that the scope of the invention is not limited to the disclosed embodiment. On the contrary, it is intended to cover various modifications and similar arrangements. The scope of the claims, therefore, should be accorded the broadest interpretation so as to encompass all such modifications and similar arrangements.

What is claimed is:

1. A method of transforming an OTP ROM manufacturing process into an ROM manufacturing process, the method comprising the steps of:
providing a substrate having two polysilicon layers formed thereon;
using an implanting energy to perform a coding step;
forming a passivation layer over the substrate;
performing a data erasing step; and
performing a test step.

2. A method according to claim 1, wherein the implanting energy is about 200 KeV to 300 KeV.

3. A method according to claim 1, wherein the two polysilicon layers comprise a floating gate and a control gate.

4. A method according to claim 1, wherein the passivation layer is an oxynitride layer.

5. A method according to claim 1, wherein the data erasing step comprises using a UV ray.

6. A method according to claim 1, wherein the coding step comprises implanting ions through the two polysilicon layers into the substrate.

7. A method of transforming an OTP ROM manufacturing process into a ROM manufacturing process, the method comprising the steps of:
providing a substrate having a polysilicon layer formed thereon;
using an implanting energy to perform a coding step; and
performing a test step.

8. A method according to claim 7, wherein the implanting energy is about 150 KeV to 200 KeV.

9. A method according to claim 7, wherein the coding step comprises implanting ions through the polysilicon layer into the substrate.

10. A method according to claim 1, wherein the polysilicon layer is a floating gate.
